(19) United States
(12) Patent Application Publication
(10) Pub. No.: US 2007/0069223 A1
(43) Pub. Date: Mar. 29, 2007

(54) LIGHT EMITTING DIODE ELEMENT AND DRIVING METHOD THEREOF

(76) Inventors: Ming-Sheng Chen, Tao-Yung Hsien (TW); Liang-Wen Wu, Tao-Yung Hsien (TW); Fen-Ren Chien, Tao-Yung Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/309,079

(22) Filed: Jun. 16, 2006

(30) Foreign Application Priority Data
Aug. 2, 2005 (TW) 94126159

(51) Int. Cl. H01L 33/00

(52) U.S. Cl. 257/88

(57) ABSTRACT

A light emitting diode (LED) element includes a substrate, a first light emitting unit, a second light emitting unit, a first electrode couple and a second electrode couple. The first light emitting unit is disposed on the substrate. The second light emitting unit is disposed on the first light emitting unit. The first electrode couple is disposed on and electrically connected with the first light emitting unit. The second electrode couple is disposed on and electrically connected with the second light emitting unit. The LED element is adapted for being driven by an alternate current for having the first light emitting unit and the second light emitting unit alternately emitting lights, thus obtaining a white light with a proper color temperature.

### CROSS-REFERENCE TO RELATED APPLICATION

This application claims the priority benefit of Taiwan application serial no. 94126159, filed on Aug. 2, 2005. All disclosure of the Taiwan application is incorporated herein by reference.

### BACKGROUND OF THE INVENTION

1. Field of the Invention

The present invention relates to light emitting diode (LED) elements and driving methods thereof, and particularly to a white light LED element and a driving method thereof.

2. Description of Related Art

LEDs are semiconductor elements, which light emitting chips are usually three-five compound semiconductors, such as gallium phosphide (GaP), gallium arsenide (GaAs) and gallium nitride (GaN). As current being applied to such compound semiconductors, electrical power is converted into optical power in a manner of counteraction of electron-cavity pairs, during which light of certain wavelength is emitted therefrom. LEDs are characterized of cold light emitting, rather than emitting light by being heated. Therefore, LEDs do not need an idling time and usually have operation lifetime up to 100,000 hours. LEDs also have advantages of faster response speed (about 10⁻⁹ second), smaller bulk, power saving, lower contamination (mercury free), higher reliability and suitable for mass production. LEDs can be widely used in the fields including light sources of scanners, backlight sources of liquid crystal displays (LCDs) or illumination apparatus. Furthermore, LEDs can be also used as white light sources because of the combination of lights having different wavelengths. Therefore, it is an important issue to develop white light LEDs for substituting conventional fluorescent lamps and incandescent lamps.

A conventional white light LED element generally comprises a blue light LED element and yellow fluorescent dyes. The blue light LED element emits a blue light and the blue light illuminates the yellow fluorescent dyes. Then the yellow fluorescent dyes are excited to emit a yellow light. The blue light and the yellow light are then mixed to form a white light. However, such a conventional white light LED element is not satisfactory at color rendering. Another conventional white light LED element is composed of an ultraviolet (UV) LED element and respectively red, green and blue fluorescent dyes. When the UV LED element emits a UV light and the UV light illuminates the red, green and blue fluorescent dyes, the red, green and blue fluorescent dyes are then excited to emit respectively a red light, a green light and a blue light. The red light, the green light and the blue light are thus mixed and a white light can be obtained. Unfortunately, because such a conventional UV LED usually performs with lower light emitting efficiency, it is hard to provide expected illumination to excite the fluorescent dyes.

In order to solve the foregoing problems of the conventional white light LEDs, a technology for directly mixing a red light, a green light and a blue light emitted respectively from a red LED, a green LED and a blue LED into a white light is proposed. However, such an LED contains three LED elements and costs much. Furthermore, driving integrated circuits for such LEDs are complicated to design. Therefore, the above-mentioned conventional white light LED is not ideal for development and manufacture.

### SUMMARY OF THE INVENTION

In view of the above, an object of the present invention is to provide an LED element having at least two light emitting units.

Another object of the present invention is to provide a driving method for LED elements, wherein driving signals in positive and negative polarities are provided respectively to a plurality of light emitting units to make the light emitting units alternately emitting lights.

According to the above and other objects, the present invention provides an LED element. The LED element includes a substrate, a first light emitting unit, a second light emitting unit, a first electrode couple and a second electrode couple. The first light emitting unit is disposed on the substrate. The second light emitting unit is disposed on the first light emitting unit. The first electrode couple is disposed on and electrically connected with the first light emitting unit. The second electrode couple is disposed on and electrically connected with the second light emitting unit.

According to an aspect of the invention, the substrate is made of a material selected from the group consisting of Al₂O₃, 6H—SiC, 4H—SiC, Si, ZnO, GaAs or MgAl₂O₄.

According to an embodiment of the present invention, the first light emitting unit includes a first semiconductor layer, a first active layer and a second semiconductor layer. The first active layer is disposed on the first semiconductor layer. The second semiconductor layer is disposed on the first active layer. In this embodiment, the first semiconductor layer and the second semiconductor layer are different from each other in doping type. Further, the first semiconductor layer includes a buffer layer, a first contacting layer and a first cover layer. The buffer layer is disposed on the substrate, and the first contacting layer is disposed on the buffer layer while the first cover layer is disposed on the first contacting layer. Moreover, the second semiconductor layer includes a second cover layer and a second contacting layer. The second cover layer is disposed on the first active layer and the second contacting layer is disposed on the second cover layer.

According to another aspect of the embodiment, the second light emitting unit includes a third semiconductor layer, a second active layer and a fourth semiconductor layer. The second active layer is disposed on the third semiconductor layer. The fourth semiconductor layer is disposed on the second active layer, and the third semiconductor layer and the fourth semiconductor layer are different from each other in doping type.

According to a further aspect of the embodiment, the third semiconductor layer includes a third contacting layer and a third cover layer. The third contacting layer is disposed on the first light emitting unit and the third cover layer is disposed on the third contacting layer. Also, the fourth semiconductor layer includes a fourth cover layer and a fourth contacting layer. The fourth cover layer is disposed on the second active layer and the fourth contacting layer is disposed on the fourth cover layer.

According to a still further aspect of the embodiment, the first electrode couple, for example, includes a first positive electrode and a first negative electrode. The first positive electrode is electrically insulated from the first negative electrode. Moreover, the LED element can further include a first transparent conductor layer. The first transparent layer is disposed on the first light emitting unit and electrically connected with the first positive electrode.

According to another aspect of the embodiment, the second electrode couple, for example, includes a second positive electrode and a second negative electrode. The second positive electrode is electrically insulated from the second negative electrode. Moreover, the LED element can further include a second transparent conductor layer. The second transparent layer is disposed on the second light emitting unit and electrically connected with the second positive electrode.

The present invention also provides a driving method adapted for driving an LED element. Wherein, the LED element includes at least a first light emitting unit and at least a second light emitting unit. The first light emitting unit and the second light emitting unit are conversely connected in parallel. The driving method for LED elements includes: providing a driving command to the LED element, the driving command including a plurality of positive signals and a plurality of negative signals, which can respectively drive the first light emitting unit and the second light emitting unit to alternately emit a first light and a second light.

According to an aspect of the method, the interval between the first light and the second light being emitted, for example, is less than 1/30 second.

According to another aspect of the method, lasting times and amplitudes of vibration of the positive signals and negative signals can be either equivalent to each other or not. The first light and the second light respectively have adjustable lasting times and illuminance, by which desired optical mixing status can be obtained.

According to the above-mentioned LED element and driving method, light of certain bandwidth and wavelength distribution is obtained by mixing lights of different wavelengths which are alternately emitted from two or more than two light emitting units.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a cross-sectional view of an LED element according to an embodiment of the invention.

FIG. 1B illustrates a wiring for the LED element of FIG. 1A and an equivalent circuit of such.

FIG. 2 is a schematic diagram illustrating a driving method for an LED element according to an embodiment of the invention.

FIG. 3 is a schematic diagram illustrating driving commands of FIG. 2.

### DESCRIPTION OF THE EMBODIMENTS

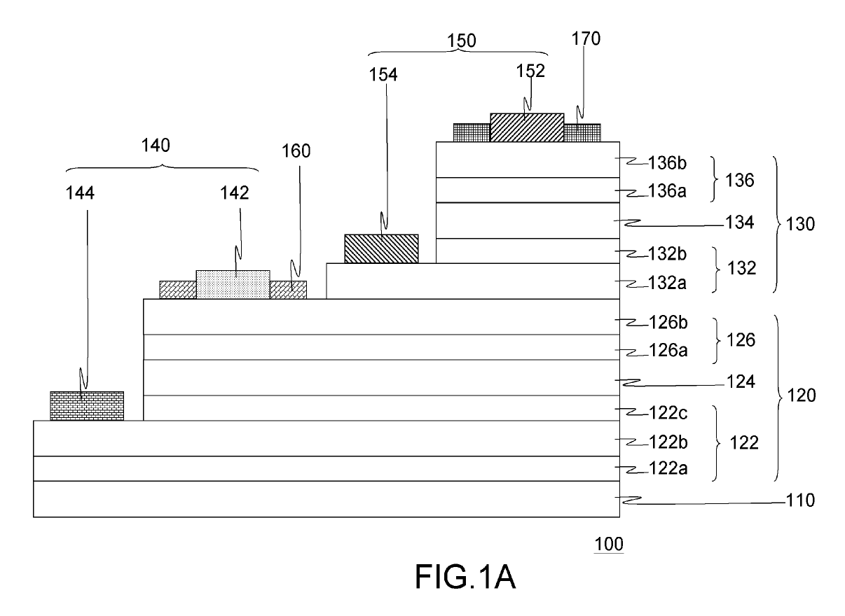

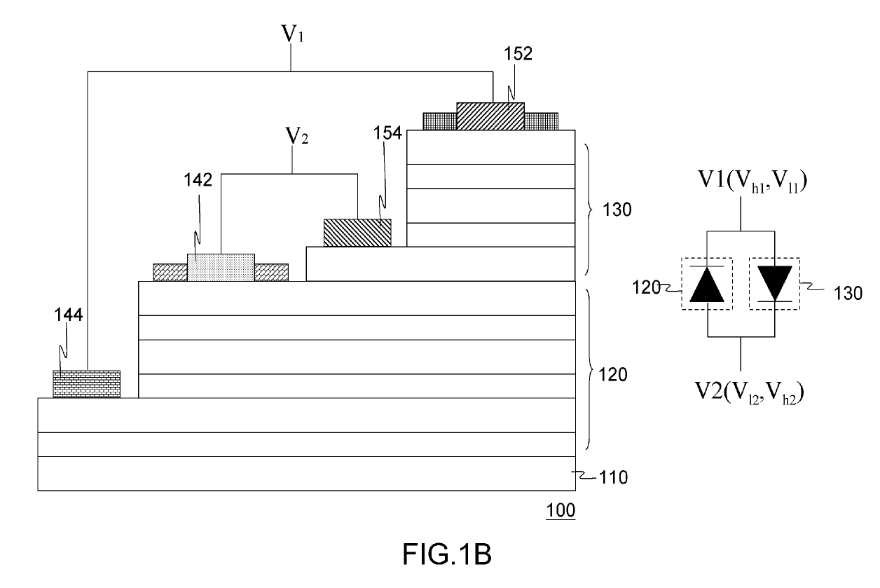

FIG. 1A is a cross-sectional view of an LED element according to an embodiment of the invention. Referring to FIG. 1A, an LED element 100 includes a substrate 110, a first light emitting unit 120, a second light emitting unit 130, a first electron couple 140 and a second electrode couple 150. The first light emitting unit is disposed on the substrate 110 and the second light emitting unit 130 is disposed on the first light emitting unit 120. The first electrode couple 140 is disposed on and electrically connected with the first light emitting unit 120. The second electrode couple 150 is disposed on and electrically connected with the second light emitting unit 130. The first light emitting unit 120 and the second light emitting unit 130 are adapted for emitting lights of different wavelengths. The first electrode couple 140 and the second electrode couple 150 function as connection ports for allowing driving commands inputted to the first light emitting unit 120 and the second light emitting unit 130. According to an aspect of the embodiment, the first light emitting unit 120 is adapted for emitting yellow light, and the second light emitting unit 130 is adapted for emitting blue light. Such a yellow light and a blue light are adapted for being mixed into a white light with a certain color temperature. However, it is to be noted that neither colors of lights emitted from the light emitting units, nor the quantity of the light emitting units are limited according to the invention. For example, three light emitting units respectively emitting red light, green light and blue light and being respectively controlled by three electrode couples can be adopted according to the invention. Further, the invention is also adapted for obtaining light of other mixed colors rather than white color light.

The LED element 100 will now be illustrated in details in paragraphs below.

Herein, the substrate 110, for example, is made of a material selected from the group consisting of Al₂O₃, 6H—SiC, 4H—SiC, Si, ZnO, GaAs or MgAl₂O₄ or other similar materials. Referring to FIG. 1A, the first light emitting unit 120, for example, includes a first semiconductor layer 122, a first active layer 124 and a second semiconductor layer 126. The second light emitting unit 130, for example, includes a third semiconductor layer 132, a second active layer 134 and a fourth semiconductor layer 136. The first active layer 124 and the second active layer 134 are respectively disposed on the first semiconductor layer 122 and the third semiconductor layer 132. The second semiconductor layer 126 and the fourth semiconductor layer 136 are respectively disposed on the first active layer 124 and the second active layer 134. Furthermore, the first electrode couple 140, for example, includes a first positive electrode 142 and a first negative electrode 144, and the second electrode couple 150, for example, includes a second positive electrode 152 and a second negative electrode 154. The first positive electrode 142 is electrically insulated from the first negative electrode 144, and the second positive electrode 152 is electrically insulated from the second negative electrode 154.

When a forward current is applied to the first light emitting unit 120 along the direction from the first positive electrode 142 to the first negative electrode 144, electrons and cavities are transferred respectively from the first semiconductor layer 122 and the second semiconductor layer 126 to the first active layer 124. The electrons and cavities then counteract thereby and release energy in the form of lights. Similarly, when a forward current is applied to the second light emitting unit 130 along the direction from the second positive electrode 152 to the second negative electrode 154, electrons and cavities are transferred respectively from the third semiconductor layer 132 and the fourth semiconductor layer 136 to the first active layer 134. The electrons and cavities then counteract thereby and release energy in the form of lights. The first active layer 124 and the second active layer 134, for example, are made of InₐGa₁₋ₐN material, wherein different percentages of indium and gallium indicate lights of different bands. Moreover, the first semiconductor layer 122 and the second semiconductor layer 126 are in different doping types, and the third semiconductor layer 132 and the fourth semiconductor layer 136 are in different doping types. In this embodiment, for example, the first semiconductor layer 122 and the third semiconductor layer 132 are n-type semiconductor layers, while the second semiconductor layer 126 and the fourth semiconductor layer 136 are p-type semiconductor layers. Also, the first positive electrode 142 and the second positive electrode 152, for example, are made of materials selected from the group consisting of: Ni, Pt, Co, Pd, Be, Au, Ti, Cr, Sn, Ta, TiN, TiWNₐ, WSiₐ or other similar materials. The first positive electrode 142 and the second positive electrode 152, for example, are composed of metals or alloys in the form of either a single layer or a multilayer. The first negative electrode 144 and the second negative electrode 154 for example are made of materials selected from the group consisting of: Al, Pt, Pd, Co, Mo, Be, Au, Ti, Cr, Sn, Ta, TiN, TiWNₐ, WSiₐ or other similar materials. The first negative electrode 144 and the second negative electrode 154, for example, are composed of metals or alloys in the form of either a single layer or a multilayer.

As seen from FIG. 1A, the first semiconductor layer 122 includes a buffer layer 122a, a first contacting layer 122b and a first cover layer 122c. The second semiconductor layer 126 includes a second cover layer 126a and a second contacting layer 126b. The third semiconductor layer 132 includes a third contacting layer 132a and a third cover layer 132b. The fourth semiconductor layer 136 includes a fourth cover layer 136a and a fourth contacting layer 136b. The buffer layer 122a is disposed on the substrate 110 and the first contacting layer 122b is disposed on the buffer layer 122a. The first cover layer 122c is disposed on the first contacting layer 122b. The second cover layer 126a is disposed on the first active layer 124 and the second contacting layer 126b is disposed on the second cover layer 126a. The third contacting layer 132a is disposed on the first light emitting unit 120 and the third cover layer 132b is disposed on the third contacting layer 132a. The fourth cover layer 136a is disposed on the second active layer 134 and the fourth contacting layer 136b is disposed on the fourth cover layer 136a.

The buffer layer 122a, for example, is made of AlₐGa_{b}In_{1-a-b}N (0≦a<1, 0≦b<1, and a+b≦1). The first contacting layer 122b and the third contacting layer 132a can be n-type contacting layers, and the first cover layer 122c and the third cover layer 132b can be n-type cover layers. The second contacting layer 126b and the fourth contacting layer 136b can be p-type contacting layers, and the second cover layer 126a and the fourth cover layer 136a can be p-type cover layers. The foregoing n-type contacting layers, n-type cover layers, p-type contacting layers and p-type cover layers, for example, are composed of GaN materials, whose characteristics are adjusted with types and concentrations of the selected dopants.

According to the embodiment, the LED element 100 may further include a transparent conductor layer 160 and a second transparent conductor layer 170. The first transparent conductor layer 160 is disposed on the first light emitting unit 120 and is electrically connected with the first positive electrode 142. The second transparent conductor layer 170 is disposed on the second light emitting unit 130 and is electrically connected with the second positive electrode 152. The first transparent conductor layer 160 and the second transparent conductor layer 170 can be metal conductive layers or transparent oxide layers. The metal conductive layer, for example, is made of materials selected from the group consisting of: Ni, Pt, Co, Pd, Be, Au, Ti, Cr, Sn, Ta, or other similar materials. The metal conductive layer, for example, is composed of metal or alloy in the form of either a single layer or a multilayer. The transparent oxide layer, for example, is made of materials selected from the group consisting of: InₐSn_{b}O (ITO), SnₐO (CTO), ZnO:Al, ZnGa₂O₄, SnO₂:Sb, Ga₂O₃:Sn, AgInO₂:Sn, In₂O₃:Zn, CuAlO₂, LaCuOS, NiO, CuGaO₂ or SrCu₂O₂. The transparent oxide layer, for example, is composed in the form of either a single layer or a multilayer.

FIG. 1B illustrates a wiring for the LED element of FIG. 1A and an equivalent circuit of such. Referring to FIG. 1B, the first negative electrode 144 and the second positive electrode 152 are respectively connected to a power supply V₁, while the first positive electrode 142 and the second negative electrode 154 are respectively connected to a power supply V₂. The power supply V₁ and the power supply V₂ are different in phase. The first light emitting unit 120 and the second light emitting unit 130 can be considered as diode elements. Therefore, the equivalent circuit of above can be considered as the first light emitting unit 120 and the second light emitting unit 130 being conversely connected in parallel and being connected to the power supply V₁ and the power supply V₂. When the power supply V₁ provides a higher voltage Vₕ₁ and the power supply V₂ provides a lower voltage Vₗ₂, the second light emitting unit 130 is under a forward bias voltage and emits a light and the first light emitting unit 120 is under a reverse bias voltage and does not emit lights. Otherwise, when the power supply V₁ provides a lower voltage Vₗ₁ and the power supply V₂ provides a higher voltage Vₕ₂, the first light emitting unit 120 is under a forward bias voltage and emits a light and the second light emitting unit 130 is under a reverse bias voltage and does not emit lights. As the phases of the power supply V₁ and the power supply V₂ periodically are changing, the first light emitting unit 120 and the second light emitting unit 130 alternately emit lights.

In this embodiment, the LED element itself includes two light emitting units for emitting lights and obtaining a white light by mixing the emitted lights therefrom, therefore such a single chip structure can largely save manufacturing cost. Furthermore, the LED element includes circuits that connect the light emitting units inside the element so that it is ready for use by simply connecting to an outside power supply.

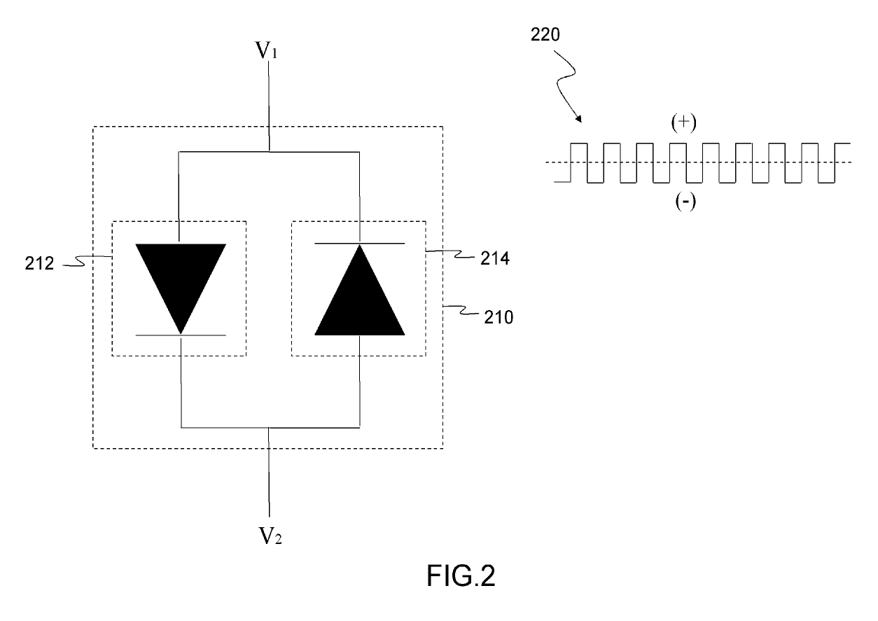

FIG. 2 is a schematic diagram illustrating a driving method for an LED element according to an embodiment of the invention. Referring to FIG. 2, the driving method for an LED element is adapted for driving an LED element 210. The LED element 210 includes a first light emitting unit 212 and a second light emitting unit 214 being conversely connected in parallel. According to an aspect of the embodiment, the first light emitting unit 212 and the second light emitting unit 214 can be disposed on either a single substrate or different substrates. The driving method for LED elements includes: providing a driving command 220 to the LED element 210; the driving command 220 includes a plurality of positive signals (+) and a plurality of negative signals (−), which can respectively drive the first light emitting unit 212 and the second light emitting unit 214 to alternately emit a first light and a second light.

In this embodiment, the LED element 210 includes two connection ports respectively connected with power supply V₁ and power supply V₂. And a preferred method for providing the driving command 220, for example, is: grounding the power supply V₂ and inputting an alternate current with the power supply V₁. Therefore, the driving command 220 is composed of a plurality of positive driving signals (+) and a plurality of negative driving signals (−) which are alternately ranged. As the LED element 210 receives a positive driving signal (+), the first light emitting unit 212 is under a forward bias voltage and emits a first light, while the second light emitting unit 214 is under a reverse bias voltage and does not emit lights. As the LED element 210 receives a negative driving signal (−), the second light emitting unit 214 is under a forward bias voltage and emits a second light, while the first light emitting unit 212 is under a reverse bias voltage and does not emit lights. Consequently, the first light emitting unit 212 and the second light emitting unit 214 alternately emit the first lights and the second lights in accordance with the driving command 220.

When a shift period between a positive driving signal and a negative driving signal of the driving command 220 is less than a time of persistence of vision, in other words, the interval between emitting a first light and emitting a second light is less than a certain time, for example less than 1/30 second, human eyes sense a single color light as mixed with the first light and the second light rather than the factual flashing lights. In the embodiment, if the first light is a yellow light and the second light is a blue light, then human eyes will sense a white light as the yellow light and the blue light are mixed.

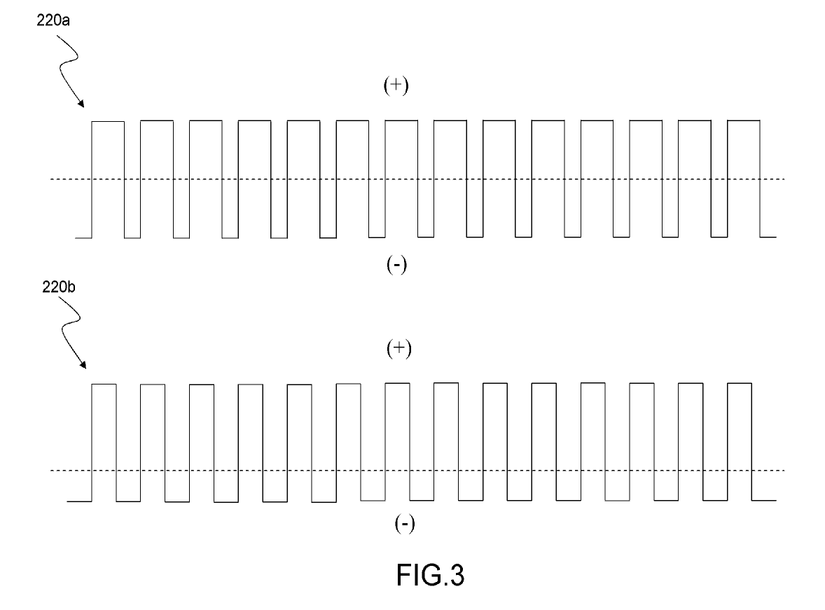

FIG. 3 is a schematic diagram illustrating driving commands of FIG. 2. Referring to FIG. 3, lasting times of the positive signals (+) and negative signals (−) can be either equivalent to each other or not. Amplitudes of vibration of the positive signals (+) and negative signals (−) can be either equivalent to each other or not.

According to a driving command 220a, lasting times of the positive signals (+) and negative signals (−) are different from each other while amplitudes of vibration of the positive signals (+) and negative signals (−) are equivalent to each other. Therefore, the driving command 220a can adjust the illuminance ratio of the first light and the second light by adjusting the lasting time of the first light and the second light, thus a desired optical mixing status is obtained. According to a driving command 220b, lasting times of the positive signals (+) and negative signals (−) are equivalent to each other while amplitudes of vibration of the positive signals (+) and negative signals (−) are different from each other. Therefore, the driving command 220b can adjust the illuminance ratio of the first light and the second light by adjusting the illuminance of the first light and the second light, thus a desired optical mixing status is obtained. However, the present invention is not limited by the above-mentioned embodiments, and the amplitude, the waveform and the frequency of the driving command are not limited according to the invention.

In summary, according to the LED element and the driving method thereof of the invention, because the LED element includes at least two light emitting units for obtaining a mixed white light, the manufacturing cost can be significantly saved. Furthermore, the LED element includes circuits that connect the light emitting units inside the element so that the outside circuit design for this LED element is relatively simple. Moreover, desired optical mixing status can be obtained by adjusting types of the driving signals.

It should be noted that specific embodiments of, and examples for, the invention are described herein for illustrative purposes, various equivalent modifications are possible within the scope of the invention, as those skilled in the relevant art will recognize that modifications and adaptations of the above-described preferred embodiments of the present invention may be made to meet particular requirements. This disclosure is intended to exemplify the invention without limiting its scope. All modifications that incorporate the invention disclosed in the preferred embodiment are to be construed as coming within the scope of the appended claims or the range of equivalents to which the claims are entitled.

What is claimed is:

1. An LED element comprising:
a substrate;
a first light emitting unit, being disposed on the substrate;
a second light emitting unit, being disposed on the first light emitting unit;
a first electrode couple, being disposed on and electrically connected with the first light emitting unit; and
a second electrode couple, being disposed on and electrically connected with the second light emitting unit.

2. The LED element according to claim 1, wherein the substrate is made of a material selected from the group consisting of Al₂O₃, 6H—SiC, 4H—SiC, Si, ZnO, GaAs or MgAl₂O₄.

3. The LED element according to claim 1, wherein the first light emitting unit comprises:
a first semiconductor layer;
a first active layer, being disposed on the first semiconductor layer; and
a second semiconductor layer, being disposed on the first active layer, wherein the first semiconductor layer and the second semiconductor layer are different from each other in doping type.

4. The LED element according to claim 3, wherein the first semiconductor layer comprises:
a buffer layer, being disposed on the substrate;
a first contacting layer, being disposed on the buffer layer; and
a first cover layer, being disposed on the first contacting layer.

5. The LED element according to claim 3, wherein the second semiconductor layer comprises:
a second cover layer, being disposed on the first active layer; and
a second contacting layer, being disposed on the second cover layer.

6. The LED element according to claim 1, wherein the second light emitting unit comprises:
a third semiconductor layer;
a second active layer, being disposed on the third semiconductor layer; and
a fourth semiconductor layer, being disposed on the second active layer, wherein the third semiconductor layer and the fourth semiconductor layer are different from each other in doping type.

7. The LED element according to claim 6, wherein the third semiconductor layer comprises:
a third contacting layer, being disposed on the first light emitting unit; and
a third cover layer, being disposed on the third contacting layer.

8. The LED element according to claim 6, wherein the fourth semiconductor layer comprises:
a fourth cover layer, being disposed on the second active layer; and
a fourth contacting layer, being disposed on the fourth cover layer.

9. The LED element according to claim 1, wherein the first electrode couple comprises:
a first positive electrode; and
a first negative electrode, wherein the first positive electrode is electrically insulated from the first negative electrode.

10. The LED element according to claim 9, further comprises a first transparent conductor layer, wherein the first transparent layer is disposed on the first light emitting unit and electrically connected with the first positive electrode.

11. The LED element according to claim 1, wherein the second electrode couple comprises:
a second positive electrode; and
a second negative electrode, wherein the second positive electrode is electrically insulated from the second negative electrode.

12. The LED element according to claim 11, further comprises a second transparent conductor layer, wherein the second transparent layer is disposed on the second light emitting unit and electrically connected with the second positive electrode.

13. A driving method for LED elements, the driving method being adapted for driving an LED element, wherein the LED element comprises at least a first light emitting unit and at least a second light emitting unit, the first light emitting unit and the second light emitting unit being conversely connected in parallel, the driving method for LED elements comprising:
providing a driving command to the LED element for driving the first light emitting unit and the second light emitting unit to alternately emit a first light and a second light, wherein the driving command comprises a plurality of positive signals and a plurality of negative signals.

14. The driving method for LED elements according to claim 13, wherein the interval between the first light and the second light being emitted is less than 1/30 second.

15. The driving method for LED elements according to claim 13, wherein lasting times of the positive signals and negative signals are different from each other.

16. The driving method for LED elements according to claim 13, wherein amplitudes of vibrations of the positive signals and negative signals are different from each other.
